(19) United States
(12) Patent Application Publication
(10) Pub. No.: US 2008/0131646 A1
(43) Pub. Date: Jun. 5, 2008

(54) Laminate for Luminescent Element, and Luminescent Element

(75) Inventor: Akira Tanaka, Tokyo (JP)

Correspondence Address: BIRCH STEWART KOLASCH & BIRCH, PO BOX 747, FALLS CHURCH, VA, 22040-0747, US

(73) Assignee: IVOCLAR VIVADENT AG, LIECHTENSTEIN (JP)

(21) Appl. No.: 11/883,224

(22) PCT Filed: Jan. 26, 2006
(86) PCT No.: PCT/JP06/01219

§ 371 Date: Jul. 27, 2007

(30) Foreign Application Priority Data
Jan. 28, 2005 (JP) 2005-021845

(51) Int. Cl. B32B 3/02; C08F 210/14

(52) U.S. Cl. 428/76; 526/72; 526/348

(57) ABSTRACT

This invention provides a laminate for a luminescent element that can be used as a protecting material for the body of luminescent elements, for example, substrates and sealing vessels for luminescent elements such as organic EL elements, is transparent, and has both a gas barrier function and a deoxygenating function. There is also provided a luminescent element comprising this laminate for a luminescent element as a substrate and/or a sealing vessel. The laminate for a luminescent element is characterized by stacking an oxygen absorbing layer (3) containing a conjugated diene polymer cyclized product having a percentage unsaturated bond reduction of not less than 10% and a gas barrier layer (1). Preferably, the laminate for a luminescent element has such properties that the oxygen absorption of the conjugated diene polymer cyclized product is not less than 5 mL/g, the rate of oxygen absorption from the surface of the oxygen absorption layer is not less than 1 mL/m²/day, the coefficient of oxygen permeability of the gas barrier layer is not more than 5.0 mL/m²/day, and the light transmittance in a wavelength region of 400 nm to 650 nm is not less than 85%.

### TECHNICAL FIELD

The present invention relates to a laminate for a luminescent element and a luminescent element, more particularly to a laminate for a luminescent element utilized for substrates and/or sealing containers for electroluminescent elements such as organic electroluminescent elements, which are called organic EL elements, and to a luminescent element employing the laminate.

### BACKGROUND ART

Organic EL elements, useful as a luminescent element, are the one, the basic structure of which is a layered structure with an organic luminescent layer placed between an anode and a cathode. An example of the organic EL element is shown in FIG. 3. The organic EL element has a substrate 11, a luminescent body of the element 10 placed on the face of the substrate 11, and a sealing container 12 for protecting the entire luminescent body 10 from the outside things. The luminescent body of the luminescent element 10 is of a layered structure with an organic luminescent layer 5 made of organic compounds that have the functions of electroluminescence, the layer 5 placed between an anode 4 and a cathode 6. The organic luminescent layer 5 may typically be composed of several sublayers, for example, a luminescent compound-containing sublayer that contains luminescent compounds, a first transporting sublayer and a hole-injecting sublayer layered on the side of the luminescent compound-containing sublayer, which side faces the cathode 6, and a second transporting sublayer and an electron-injecting sublayer layered on the opposite side of the luminescent compound-containing sublayer, which opposite side faces the anode 4. The substrate 11 is made of, for example, glass, ceramic, or plastic. An example of materials for the sealing container 12 is metal. An organic EL panel is composed by arranging many such organic EL elements on a same substrate 11. Instead of arranging sealing containers consecutively may be employed a method of sealing the organic EL elements with a sealing plate in the production of an organic EL panel.

Although organic EL elements are a very efficient luminescent element, they are prone to quickly deteriorate by oxygen gas and moisture because organic luminescent layers include organic compounds that are relatively unstable. Because of this defect, organic EL elements need to be protected from oxygen gas and/or moisture by the substrate and the sealing container. In order to achieve an effective protection, a chemicals disposition corner 8 is provided in the space within the sealing container, as shown in FIG. 3, which corner contains a desiccant together with an inorganic deoxidant to remove substances that cause the organic luminescent layer to deteriorate, such as oxygen gas and moisture.

Patent Document 1 also teaches forming a protective cover made of a fluorine polymer or an oxide insulating material, on the outer faces of the laminate including the organic luminescent layer sandwiched between the anode and the cathode; placing the laminate with the protective cover in a glass container; also placing a desiccant and a deoxidant in the space between the protective cover and the inner faces of the glass container; and filling the space with an inert medium. Patent Document 2 discloses an organic EL element device including an organic EL element, the sides of which are sealed with an epoxy resin adhesive including a deoxidant. Patent Document 3 teaches the use of an ultraviolet curing resin as an adhesive to stick the substrate of a plastic organic EL panel to the laminate.

Patent Document 1: JP 10-275682 ('98) A, or U.S. Pat. No. 5,990,615 A
Patent Document 2: JP 2002-175877 A, or U.S. Pat. No. 6,686,063 B2

### Patent Document 3: JP 2004-47381 A, or WO 2004/8812 A1

### DISCLOSURE OF THE INVENTION

### Problems to be Solved by the Invention

Although various attempts to make longer the life of an organic EL element have been done as mentioned above, the development of excellent materials and methods for completely isolating the luminescent body of the luminescent element from the outside for a long time has still been a waited. In particular, it was difficult to protect the stuck part between the substrate and the sealing container, the flexible substrate, and the sealing container of flexible organic EL panels from the invasion of oxygen gas. To attend to this difficulty, organic EL elements with sealing containers that include deoxidants within them have been developed, as mentioned above. However, the development of organic EL panels with flexibility that does not require a deoxidant inside the sealing container to isolate the luminescent body from the outside atmosphere for a long time has been demanded.

In view of these situations, the objective of the present invention is to solve the problems of conventional organic EL elements, and to provide a laminate for a luminescent element with a gas-barrier function and a deoxidizing function, suitably used for materials for protective members, such as the substrate and/or the sealing container, of the luminescent body of the luminescent element, and further a luminescent element utilizing the laminate for the substrate and/or the sealing container.

### Means to Solve the Problems

Means to solve the problems are:

(1) A laminate for a luminescent element, comprising an oxygen-absorbing layer including a cyclized conjugated diene polymer obtained by subjecting a conjugated diene polymer to a cyclizing reaction, having a degree of decrease in unsaturated bonds, which is the ratio of the number of the unsaturated bonds in the cyclized conjugated diene polymer to that of the unsaturated bonds in the conjugated diene polymer, of not less than 10%, and a gas-barrier layer.
(2) The laminate according to item (1), wherein the cyclized conjugated diene polymer has an oxygen absorption of not less than 5 mL/g.
(3) The laminate according to item (1), wherein the oxygen-absorbing layer absorbs oxygen from its surface at a rate of not less than 1 mL/m²/day.
(4) The laminate according to item (1), wherein the cyclized conjugated diene polymer is a modified cyclized conjugated diene polymer.
(5) The laminate according to item (1), wherein the gas-barrier layer has an oxygen permeability of not more than 5 mL/m²/day.
(6) The laminate according to item (1), wherein the laminate has a light transmittance of not less than 85% at a wavelength ranging between 400 nm and 650 nm.
(7) The laminate according to item (1), wherein the conjugated diene polymer is a copolymer of a conjugated diene monomer and at least one other monomer.
(8) The laminate according to item (7), wherein said other monomer is styrene.
(9) A luminescent element comprising a substrate, an luminescent body of the luminescent element placed on the substrate, and a sealing container so placed that the sealing container covers the entire luminescent body, wherein the substrate and/or the sealing container is formed from the laminate for a luminescent element according to item (1) above.

### Advantages of the Invention

The laminate for a luminescent element according to the present invention has a gas-barrier function together with a deoxidizing function, which laminate can be applied to, for example, a substrate for a luminescent element such as organic EL elements, and/or a material for physically protecting a luminescent element such as a sealing container. The laminate for a luminescent element according to the present invention absorbs and removes oxygen gas existing within the sealing container, and prevents gas, especially oxygen gas, from entering the sealing container, which laminate can also be utilized as a material for protecting luminescent elements that has a long life and deteriorates little. Furthermore, a luminescent element employing this laminate for a luminescent element for the substrate and/or the sealing container is free of deterioration for a long time, and the transparence of the laminate makes it possible to send out light from the side of the sealing container of the luminescent element as well as from the side of the substrate thereof. Moreover, luminescent panels employing this luminescent element can easily be produced, and the produced are thin luminescent panels with excellent flexibility and a long life.

### BRIEF DESCRIPTION OF THE DRAWINGS

FIG. 1 is an illustration of an example of a luminescent element with the laminate for a luminescent element according to the present invention.

FIG. 2 is an illustration of another example of a luminescent element with the laminate for a luminescent element according to the present invention.

FIG. 3 is an illustration of a conventional organic EL element.

FIG. 4 is an illustration of the layered structure of a laminate for a luminescent element according to the present invention.

FIG. 5 is an illustration of the layered structure of another laminate according to the present invention.

FIG. 6 is an illustration of the layered structure of still another laminate according to the present invention.

FIG. 7 is an illustration of the layered structure of a further laminate according to the present invention.

FIG. 8 is an illustration of the layered structure of a still further laminate according to the present invention.

FIG. 9 is an illustration of the layered structure of another laminate according to the present invention.

FIG. 10 is an illustration of the layered structure of still another laminate according to the present invention.

### EXPLANATION OF REFERENCE NUMERALS

1 . . . gas-barrier layer; 1′ . . . gas-barrier layer with the function of a protective resin layer; 2 . . . protective resin layer; 3 . . . oxygen-absorbing layer; 3′ . . . oxygen-absorbing layer with the function of a protective resin layer; 4 . . . anode; 5 . . . organic luminescent layer; 6 . . . cathode; 8 . . . chemicals disposition corner; 10 . . . luminescent body of the luminescent element; 11 . . . substrate; 12 . . . sealing container; 13 . . . luminescent element; 14 . . . laminate for a luminescent element

### BEST MODE TO CARRY OUT THE INVENTION

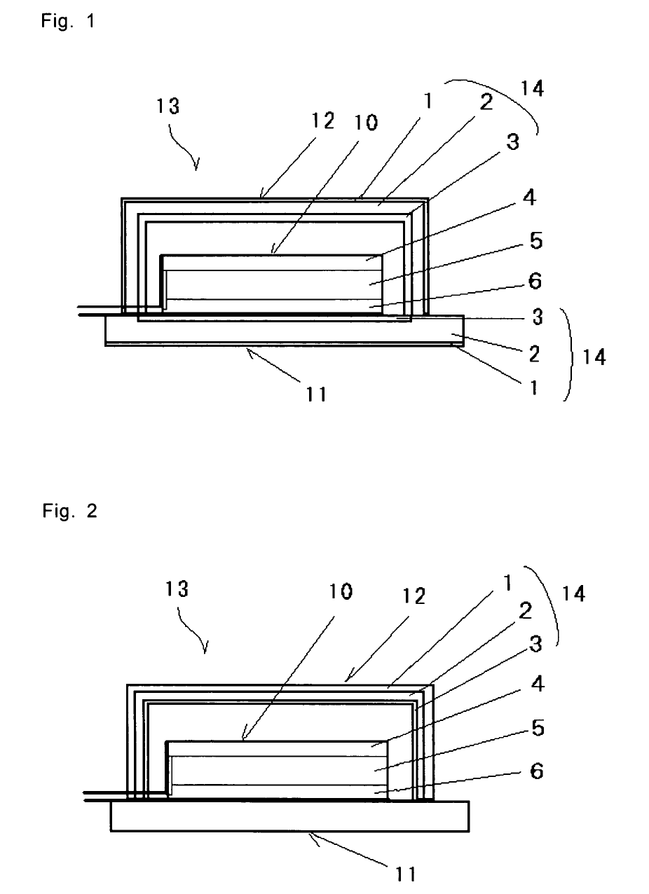

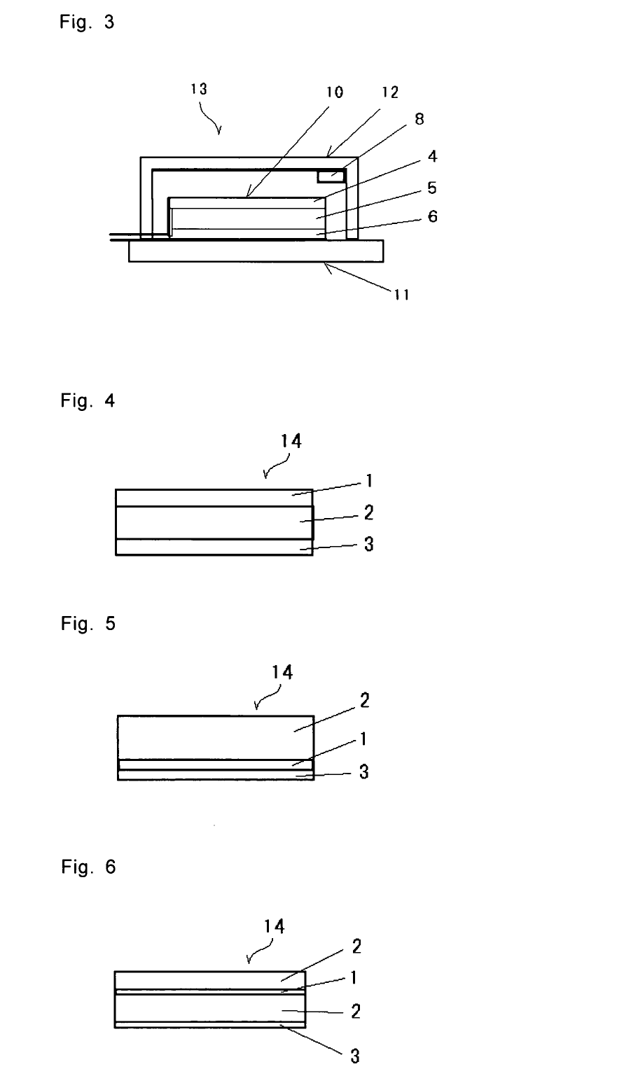

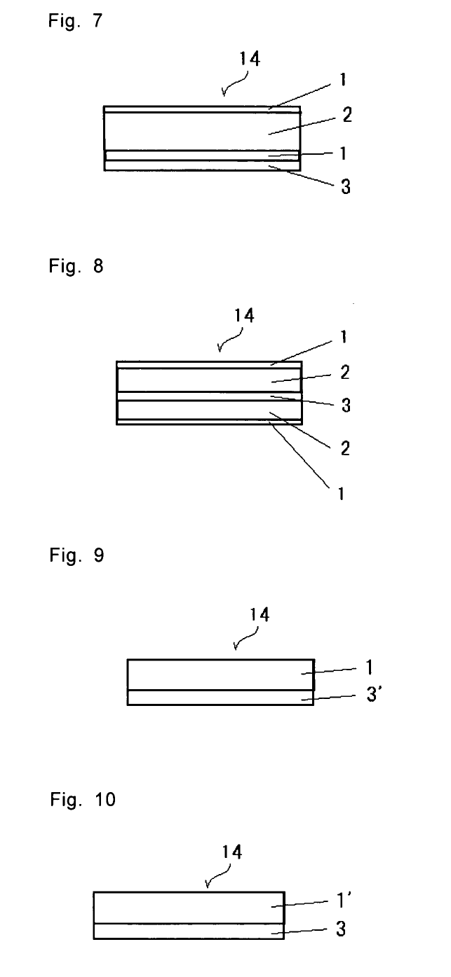

The laminate for a luminescent element according to the present invention is made by layering at least an oxygen-absorbing layer and a gas-barrier layer. The laminate for a luminescent element 14 has a basic layered structure in which a gas-barrier layer 1, a protective resin layer 2, and an oxygen-absorbing layer 3 are layered in this order, as shown in, for example FIG. 4. The laminate 14 according to the present invention may have another layered structure, for example as shown in FIG. 5, composed of a protective resin layer 2, a gas-barrier layer 1, and an oxygen-absorbing layer 3, layered in this order. When the laminate, such as these examples, is used for a luminescent element, the layers may be so arranged that the oxygen-absorbing layer 3 is at a more inside location than the gas-barrier layer 1, or as shown in FIG. 1, at a location closer to the space where an organic luminescent layer 5 exists, or at the side of the sealed space. The laminate 14 has many other ways of layering the layers. One example is a four-layer structure, as shown in FIG. 6, composed of a protective resin layer 2, a gas-barrier layer 1, another protective resin layer 2, and an oxygen-absorbing layer 3, layered in this order. Another example is also a four-layer structure, as shown in FIG. 7, having a gas-barrier layer 1, a protective resin layer 2, another gas-barrier layer 2, and an oxygen-absorbing layer 3, layered in this order. As a special example, gas-barrier layers 1 may be placed on both sides of an oxygen-absorbing layer 3, as shown in FIG. 8. The laminate may further take a layered structure of a gas-barrier layer 1 and an oxygen-absorbing layer with the function of the protective resin layer 3′, or a layered structure of a gas-barrier layer with the function of the protective resin layer 1′ and an oxygen-absorbing layer 3, as shown in FIG. 10.

The laminate for a luminescent element according to the present invention has at least two layers of a gas-barrier layer and an oxygen-absorbing layer. The laminate should be structured in such a way that the gas-barrier layer prevents oxygen gas from entering the organic luminescent layer from the outside, while the oxygen-absorbing layer absorbs oxygen gas that has been present in the sealed space and/or a small amount of oxygen gas that has permeated through the gas-barrier layer. It is preferable if the laminate for a luminescent layer according to the present invention further has a protective resin layer with a function of maintaining the mechanical strength of the laminate. Examples of the structure with a protective resin layer are shown in FIGS. 4 and 5. The protective resin layer may be an independent layer or the function may be incorporated into the gas-barrier layer or the oxygen-absorbing layer. The laminate for a luminescent element according to the present invention may have, for example, a plurality of protective layers, oxygen-absorbing layers, and/or gas-barrier layers, as long as it has a layered structure with the functions explained above. For example, the laminate may take the structure shown in FIG. 6, 7, or 8. On the other hand, the laminate for a luminescent element according to the present invention may have a structure composed of two layers, the gas-barrier layer and the oxygen-absorbing layer, if the oxygen absorbing-layer has a sufficient mechanical strength and the function of a protective layer to such an extent that the oxygen-absorbing layer can be considered to double as a protective layer. An example of this structure is shown in FIG. 9. Or the laminate for a luminescent element according to the present invention may be composed of two layers of the gas-barrier layer and the oxygen-absorbing layer, if the gas-barrier layer has a sufficient thickness and the function of a protective layer. See, for example, the structure shown in FIG. 10.

The laminate for a luminescent element according to the present invention should have a light transmittance of not less than 85% at a wavelength ranging between 400 nm and 650 nm. Preferably light can be emitted from both sides of a luminescent element employing the laminate according to the present invention, as we will explain hereinafter. For this purpose, it is desirable that the light transmittance of the laminate through which the generated light passes should be high. Especially in the range of wavelengths of light emitted by organic EL elements, the light transmittance of the laminate should be not less than 85%, more preferably not less than 90%, particularly preferably not less than 95%. The wavelength of light emitted by organic EL elements typically ranges from 400 nm to 650 nm. Therefore it is desirable that the laminate should have high light transmittance at all the wavelengths through the range. When this laminate is applied to an organic EL element that emits light, the wavelengths of which are in a smaller particular range, it will be enough if the laminate has a light transmittance satisfying the numerical requirement described above at wavelengths in this particular range. In some cases, it is sufficient if the average of the values of the light transmittance in the entire wavelength range satisfies the requirement. The light transmittance at a wavelength from 400 nm to 650 nm may be measured with a commercial turbidimeter in accordance with JIS K7361-1.

In the present invention, the cyclized conjugated diene polymer plays an important part, and I will explain it first. The cyclized conjugated diene polymer may be obtained by subjecting a conjugated diene polymer to a cyclization reaction in the presence of an acid catalyst. The obtained cyclized conjugated diene polymer includes rings originating from the conjugated diene monomer units. The conjugated diene polymer may include a homopolymer of a conjugated diene monomer or a copolymer of different kinds of conjugated diene monomers, or a copolymer of at least one conjugated diene monomer and monomers copolymerizable with the conjugated diene monomer. There is no limitation on the conjugated diene monomer employed. Examples of the conjugated diene monomer may include 1,3-butadiene, isoprene, 2,3-dimethyl-1,3-butadiene, 2-phenyl-1,3-butadiene, 1,3-pentadiene, 2-methyl-1,3-pentadiene, 1,3-hexadiene, 4,5-diethyl-1,3-octadiene, and 3-butyl-1,3-octadiene. These monomers may be used singly or a combination of two or more of them may be used. Among them 1,3-butadiene and isoprene are preferable, with isoprene more preferable.

There is no particular limitation on the other monomers copolymerizable with the conjugated diene monomers. Specific examples of the monomers may include aromatic vinyl monomers such as styrene, o-methylstyrene, m-methylstyrene, 2,4-dimethylstyrene, an ethylstyrene, p-t-butylstyrene, α-methylstyrene, α-methyl-p-methylstyrene, o-chlorostyrene, m-chlorostyrene, p-chlorostyrene, p-bromostyrene, 2,4-dibromostyrene, and vinylnaphthalene; linear olefin monomers such as ethylene, propylene, and 1-butene; cycloolefin monomers such as cyclopentene and 2-norbornene; non-conjugated diene monomers such as 1,5-hexadiene, 1,6-heptadiene, 1,7-octadiene, dicyclopentadiene, and 5-ethylidene-2-norbornene; (meth) acrylic acid esters such as methyl (meth)acrylate, and ethyl (meth)acrylate; and (meth)acrylonitrile, and (meth)acrylamide. Among them, aromatic vinyl monomers are preferable. Styrene and α-methylstyrene are more preferable, with styrene particularly preferable. These monomers may be used singly, or two or more of them may be used in combination.

The amount of the conjugated diene monomer units in a conjugated diene polymer may appropriately be selected from such a range that the advantages of the present invention are not marred. The amount is typically 40% by mole or more, preferably 60% by mole or more, more preferably 80% by mole or more. When the amount of the conjugated diene monomer units is too small, it is difficult to raise the degree of decrease in unsaturated bonds and the obtained is prone to be inferior in the oxygen absorption.

Examples of the conjugated diene polymer include natural rubber (NR), styrene-butadiene rubber (SBR), polyisoprene rubber (IR), polybutadiene rubber (BR), iroprene-isobutyrene copolymer rubber (IIR), ethylene-propylene-diene copolymer rubbers, and butadiene-isoprene copolymer rubber (BIR). Among them, polyisoprene rubber and polybutadiene rubber are preferable, with polyisoprene rubber more preferable.

The conjugated diene polymer may be produced by known polymerization methods. For example, it may be obtained by suspension polymerization, solution polymerization, or emulsion polymerization in the presence of an appropriate catalyst, such as a Ziegler catalyst including titanium as catalyst component, an alkyl lithium polymerization catalyst, or a radical polymerization catalyst. The cyclized conjugated diene polymer employed in the present invention may be obtained by subjecting the conjugated diene polymer to a cyclization reaction in the presence of an acid catalyst. Known catalysts may be used for the acid catalyst, and examples thereof include an organic sulfonic acid such as sulfuric acid, fluoromethane sulfonic acid, difluoromethane sulfonic acid, p-toluenesulfonic acid, xylenesulfonic acid, an alkylbenzenesulfonic acid having an alkyl group with 2 to 18 carbon atoms, and an anhydride or an alkyl ester of these compounds; and a metal halide such as boron trifluoride, boron trichloride, tin tetrachloride, titanium tetrachloride, aluminum chloride, diethyl aluminum monochloride, ethyl ammonium dichloride, aluminum bromide, antimony pentachloride, tungsten hexachloride, and iron chloride. These acid catalysts may be used singly, or two or more of them may be used in combination. Among them the organic sulfonic acid is preferable, with p-toluene sulfonic acid and its anhydride more preferable. The amount of the acid catalyst employed is typically from 0.05 to 10 parts by mass, preferably from 0.1 to 5 parts by mass, more preferably from 0.3 to 2 parts by mass, to 100 parts by mass of the conjugated diene polymer.

The cyclization reaction is carried out typically by dissolving the conjugated diene polymer in a hydrocarbon solvent, which is followed by the reaction in the presence of the acid catalyst. There is no limitation on the hydrocarbon solvent, as long as the solvent does not hinder the cyclization reaction. Examples of the hydrocarbon solvent include an aromatic hydrocarbon such as benzene, toluene, xylene, and ethylbenzene; an aliphatic hydrocarbon such as n-pentane, n-hexane, n-heptane, and n-octane; and an alicyclic hydrocarbon such as cyclopentane and cyclohexane. When these hydrocarbon solvents are used for the polymerization reaction of the conjugated diene monomers, these solvents may also be used for the cyclization reaction subsequently. In this case, an acid catalyst is added to the polymer product liquid after the polymerization reaction is terminated, and then the product liquid with the acid catalyst may be subjected to the cyclization reaction. The hydrocarbon solvent should be used in such an amount that the solids content is normally from 5 to 60% by mass, preferably from 20 to 40% by mass. Although the cyclization reaction may be carried out under an increased pressure, a reduced pressure, or atmospheric pressure, the reaction should be done under atmospheric pressure from the viewpoint of simplicity of the operation. If the reaction is done in a dried stream, especially in an atmosphere of dried nitrogen gas or dried argon gas, side reactions caused by moisture can be reduced. The reaction temperature and the reaction time of the cyclization reaction may be determined according to those of conventional similar reactions. The reaction temperature is normally from 50 to 150° C., preferably from 40 to 110° C., and the reaction time is typically from 0.5 to 10 hours, preferably from 2 to 7 hours. After the termination of the cyclization reaction, the acid catalyst is deactivated in the usual way and the acid catalyst residue is removed. If desired, an antioxidant may be added to the obtained. Then, the hydrocarbon solvent and unreacted vinyl compounds having polar groups are removed, which provides a solid cyclized conjugated diene polymer product.

For the cyclized conjugated diene polymer employed in the present invention, modified cyclized conjugated diene polymers are preferred to non-modified cyclized conjugated diene polymers, as long as the employment of such modified cyclized conjugated diene polymers does not hinder the achievement of the objective of the present invention. Among the modified cyclized conjugated diene polymers are preferred modified cyclized conjugated diene polymers having polar groups obtained by so modifying the cyclized conjugated diene polymers that they have polar groups. There is no limitation on the polar groups. Examples of the polar groups include an acid anhydride group, carboxyl group, hydroxyl group, thiol radical, an ester group, epoxy group, amino group, amide group, cyano group, silyl group, and a halogen.

The acid anhydride group and the carboxyl group on the cyclized conjugated diene polymer may be formed, for example, by the addition of a vinyl carboxylic acid, such as maleic anhydride, itaconic anhydride, aconitic anhydride, norbornene dicarboxylic acid anhydride, acrylic acid, and methacrylic acid, to the cyclized conjugated diene polymer. Among them, the group made by the addition of maleic anhydride to cyclized polyisoprene is preferable from the viewpoint of the reactivity and the economic reasons.

The hydroxyl group on the cyclized conjugated diene polymer may be formed, for example, by the addition of a hydroxyalkyl ester of an unsaturated acid, such as 2-hydroxyethyl (meth)acrylate and 2-hydroxypropyl (meth)acrylate; an unsaturated acid amide, such as N-methylol (meth)acrylamide and N-(2-hydroxyethyl) (meth)acrylamide; a polyalkylene glycol monoester of an unsaturated acid, such as polyethylene glycol mono (meth)acrylate, polypropylene glycol mono(meth)acrylate, and poly(ethylene glycol-propylene glycol) mono(meth)acrylate; and a polyol monoester of an unsaturated acid, such as glycerol mono (meth)acrylate, to the cyclized conjugated diene polymer. Among them, the group formed from a hydroxyalkyl ester of an unsaturated acid is preferable. Particularly preferable are the group made by the addition of 2-hydroxyethyl acrylate to the cyclized conjugated diene polymer and the group made by the addition of 2-hydroxyethyl methacrylate to the polymer. Note that, for example, 2-hydroxyethyl (meth)acrylate means 2-hydroxyethyl acrylate and/or 2-hydroxyethyl methacrylate in this specification. More generally, in this specification compounds or groups including the expression of “(meth) acryl” are compounds or groups including acrylic and/or methacrylic residues.

Examples of other vinyl compounds including polar groups may be methyl (meth)acrylate, ethyl (meth)acrylate, butyl (meth)acrylate, glycidyl (meth)acrylate, dimethylaminoethyl (meth)acrylate, dimethylaminopropyl (meth)acrylate, (meth)acrylamide, and (meth)acrylonitrile.

There is no limitation on the proportion of the modified parts to the modified cyclized conjugated diene polymer, especially on the amount of the polar groups included in the cyclized conjugated diene polymer having polar groups. Generally, the amount is from 0.1 to 200 millimoles to 100 grams of the modified cyclized conjugated diene polymer. The amount is preferably from 1 to 100 millimoles, more preferably from 5 to 50 millimoles. When the amount is too small or too large, the obtained is prone to be inferior in the oxygen absorption. Note that the amount of the polar groups is defined in such a way that when the total weight of the polar groups bonded to the modified cyclized conjugated diene polymer equals the molecular weight of the polar group, the amount of the polar groups is considered to be 1 mole.

The method of producing the modified cyclized conjugated diene polymer includes (1) introducing a vinyl compound including a polar group into the modified cyclized conjugated diene polymer by addition reaction, (2) subjecting a conjugated diene polymer with polar groups to the cyclization reaction by the method explained above, (3) introducing polar groups into a conjugated diene polymer without polar groups by addition reaction and subjecting the conjugated diene polymer with the polar groups to the cyclization reaction, (4) further introducing vinyl compounds having polar groups into the modified cyclized conjugated diene polymer obtained in method (2) or (3). Among them preferable is method (1), from the viewpoint of excellent adjustability of the degree of decrease in unsaturated bonds.

Any vinyl compound having a polar group can be used for the invention, as long as it is capable of introducing polar groups into the cyclized conjugated diene polymer. Preferable examples of the vinyl compound having a polar group include vinyl compounds with polar groups such as an acid anhydride group, carboxyl group, hydroxyl group, thiol radical, an ester group, epoxy group, amino group, amide group, cyano group, silyl group, and a halogen.

The vinyl compound with an acid anhydride group or carboxyl group may include, for example, maleic anhydride, itaconic anhydride, aconitic anhydride, norbornene dicarboxylic acid anhydride, acrylic acid, methacrylic acid, and maleic acid. Among them, maleic anhydride is preferable from the viewpoint of reactivity and economic factors. For the vinyl compound having a hydroxyl group, preferable is, for example, a hydroxyalkyl ester of an unsaturated acid. Particularly preferable are 2-hydroxyethyl acrylate and 2-hydroxyethyl methacrylate.

Any method may be employed to introduce the vinyl compound having a polar group into the cyclized conjugated diene polymer by addition reaction as long as it works as intended. Typically, the addition reaction may be carried out by a conventional method, generally known as the ene reaction or the graft polymerization. This addition reaction is carried out by contacting the cyclized conjugated diene polymer with the vinyl compound having a polar group, if necessary, in the presence of a free radical initiator. The free radical initiator may include a peroxide such as di-tert-butyl peroxide, dicumyl peroxide, and benzoyl peroxide; and an azonitrile such as azobisisobutyronitrile.

Although the addition reaction may be carried out either in a solid phase or in a solution phase, the reaction in a solution phase is recommended because the control of the reaction is easy. The reaction solvent to be used may be, for example, the same as the inert solvents listed in the explanation of the cyclization reaction. The amount of the vinyl compound having a polar group varies depending on the reaction conditions. The amount should appropriately be decided so that the amount of the introduced polar groups is within the preferable range explained above.

Although the reaction for introducing the polar groups may be carried out under an increased pressure, a decreased pressure, or atmospheric pressure, the reaction should be done under atmospheric pressure from the viewpoint of simplicity of the operation. If the reaction is done in a dried stream, especially in an atmosphere of dried nitrogen gas or dried argon gas, side reactions caused by moisture can be reduced. The reaction temperature and the reaction time of this reaction may be determined according to those of conventional similar reactions. The reaction temperature is normally from 30 to 250° C., preferably from 60 to 200° C., and the reaction time is typically from 0.5 to 5 hours, preferably from 1 to 3 hours.

The cyclized conjugated diene polymer, other than 100% cyclized ones, has at least linear unsaturated bonds present in the linear portions of the polymer and cyclic unsaturated bonds present in the cyclized portions of the polymer. The portions including the cyclic unsaturated bonds are considered to make a significant contribution to oxygen absorption, while the portions including the linear unsaturated bonds are considered to little contribute to it. In other words, the presence of the cyclic unsaturated bonds in the cyclized conjugated diene polymer, which is obtained by subjecting the conjugated diene polymer to the cyclization reaction, is the key to the exhibition of the oxygen absorption function. Thus, the cyclized conjugated diene polymer with not less than 10% of the degree of decrease in unsaturated bonds, which means the ratio of the number of the unsaturated bonds in the cyclized conjugated diene polymer to that of the unsaturated bonds in the conjugated diene polymer before the cyclization, can be employed for the material for the oxygen-absorbing layer of the laminate for a luminescent element according to the present invention. The degree of decrease in unsaturated bonds should preferably be from 40 to 75%, more preferably from 55 to 70%. If the proportion is too small, the polymer is prone to be inferior in oxygen absorption. The cyclized conjugated diene polymer whose degree of decrease in unsaturated bonds is not more than the upper limit of the preferable range is capable of preventing the cyclized conjugated diene polymer from becoming brittle, making the production easy, and checking the gelation during the production. As a result, the obtained has an improved transparency, which leads to a variety of applications thereof. Furthermore, if the degree of decrease in unsaturated bonds exceeds 50%, the cyclized conjugated diene polymer gains adhesion, which may also be utilized. Also, a mixture of cyclized conjugated diene polymers with different degrees of decrease in unsaturated bonds may be used as cyclized conjugated diene polymer. For example, a mixture of a first cyclized conjugated diene polymer whose degree of decrease in unsaturated bonds is a bout 10% and a second cyclized conjugated diene polymer whose degree of decrease in unsaturated bonds is about 60% will work well.

The degree of decrease in unsaturated bonds is an index to show the degree of the reduction of the unsaturated bonds by the cyclization reaction in the conjugated diene monomer parts of the conjugated diene polymer, and the proportion is obtained in the following way. Specifically, a first ratio of the area of the peaks by the protons directly bonded to the double bonds to the area of the entire proton peaks in the conjugated diene monomer parts of the conjugated diene polymer is obtained through proton magnetic resonance, and a second ratio the area of the peaks by the protons directly bonded to the double bonds to the area of the entire proton peaks in the conjugated diene monomer parts of the cyclized conjugated diene polymer is obtained in the same way. Then, the degree of decrease of the second ratio to the first ratio is calculated.

The calculation is done according to following equations. In the equations, “SBT” denotes the area of the entire proton peaks and “SBU” the area of the peaks by the protons directly bonded to the double bonds, in the conjugated diene monomer parts of the conjugated diene polymer. “SAT” denotes the area of the entire proton peaks and “SAU” the area of the peaks by the protons directly bonded to the double bonds, in the conjugated diene monomer parts of the cyclized conjugated diene polymer. Then, “SB”, which denotes the proportion of the area of the peaks by the protons directly bonded to the double bonds to the area of the entire proton peaks before the cyclization, is expressed by: SB=SBU/SBT. On the other hand, “SA”, which denotes the proportion of the area of the peaks by the protons directly bonded to the double bonds to the area of the entire proton peaks after the cyclization, is expressed by: SA=SAU/SAT. Therefore the degree of decrease in unsaturated bonds is expressed by the following equation:

The degree of decrease in unsaturated bonds (%)=100×(SB−SA)/SB

On the other hand, to what extent the conjugated diene polymer is cyclized can also be evaluated by the degree of cyclization. The degree of cyclization can be obtained by proton magnetic resonance in accordance with the methods taught in document (a) or (b) below.

(a) M. a. Golub and J. Heller. Can. J. Chem, 41, 937 (1963)
(b) Y. Tanaka and H. Sato, J. Poiym. Sci: Poiy. Chem. Ed., 17, 3027 (1979)

The cyclized conjugated diene polymer employed in the present invention has an oxygen absorption of not less than 5 mL/g, preferably not less than 10 mL/g. The oxygen absorption is the amount of oxygen gas, in the unit of mL, absorbed in 1 g of the cyclized conjugated diene polymer under the conditions where the cyclized conjugated diene polymer is ground to powder or formed into a film and the polymer in the form of powder or a film is made to absorb oxygen gas sufficiently to saturation at 23° C. When the oxygen absorption is smaller than the value indicated above, a large amount of cyclized conjugated diene polymer is necessary to absorb oxygen gas stably for a long time. The oxygen absorption has correlation mainly with the degree of decrease in unsaturated bonds of the cyclized conjugated diene polymer.

When the oxygen absorption of the cyclized conjugated diene polymer is 50 mL/g, the possible amount of oxygen gas absorbed in 1 cm² of the oxygen-absorbing layer with a thickness of 100 μm is 0.5 mL. When the area of the same layer is 1 m², the amount is 5,000 mL/cm². Supposing that the oxygen-absorbing layer continues absorbing oxygen gas for six years, it will be capable of absorbing it at a rate of more than 833 mL/m²/year or 2.28 mL/m²/day. In order to have an ability of absorbing oxygen gas at a rate of not less than 0.9 mL/m²/day, the oxygen absorbing layer should have a thickness of not less than 40 μm, preferably not less than 70 μm, more preferably not less than 100 μm, particularly preferably not less than 200 μm.

In the present invention, a desirable rate of oxygen absorption from the surface of the oxygen absorbing layer is not less than 1 mL/m²/day, preferably not less than 5 mL/m²/day, more preferably not less than 10 mL/m²/day. Even though the cyclized conjugated diene polymer has a large ability of absorbing oxygen gas, the polymer with a too small oxygen absorption rate may not sufficiently absorb oxygen gas entering the laminate from the side of the gas-barrier layer but allow it permeate into the layer. Also, when the cyclized conjugated diene polymer is used for the material of the sealing container of a luminescent element, oxygen gas, which is present in the sealed space or enters the space for some reasons, has to be quickly absorbed and removed by the oxygen-absorbing layer. Also from this point of view, a cyclized conjugated diene polymer with the oxygen absorption rate described above should be desirable. The oxygen absorption rate is expressed by the amount of absorbed oxygen gas per unit area after 24 hours from the beginning of measurement of the amount of absorbed oxygen.

The mass average molecular weight of the cyclized conjugated diene polymer should be preferably from 5,000 to 2,000,000, more preferably from 10,000 to 1,000,000, further more preferably from 20,000 to 500,000. When the mass average molecular weight is too small, the oxygen absorption of the cyclized conjugated diene polymer is apt to be lowered. On the other hand, the mass average molecular weight is too large, the cyclized conjugated diene polymer is prone to have small fluidity and plasticity when it is produced and used, which makes it difficult to handle the polymer. The mass average molecular weight is a value reduced from that of standard polystyrene measured by gel permeation chromatography.

There is no special limitation on the glass transition temperature (Tg) of the cyclized conjugated diene polymer. Although the glass transition temperature may be selected appropriately depending on the use of the polymer, the temperature is typically from 0 to 250° C., preferably from 30 to 180° C., particularly preferably from 40 to 150° C. If the glass transition temperature of the cyclized conjugated diene polymer is outside these ranges, the cyclized conjugated diene polymer may have problems with the formability thereof, the strength of the members, the adhesion thereof with other members, and the easiness of handling. The glass transition temperature of the cyclized conjugated diene polymer may be adjusted by appropriately selecting monomers used as raw material, the molecular weight of the cyclized conjugated diene polymer, and/or the degree of decrease in unsaturated bonds.

To the cyclized conjugated diene polymer according to the present invention may be added various additives, such as an antioxidant, a catalyst the function of which is to improve oxygen absorption, a light initiator, a heat stabilizer, materials for adhesion, a reinforcing agent, fillers, a fire retardant, coloring agents, a plasticizer, a ultraviolet absorber, a lubricant, a desiccant, a deodorant, an antistatic additive, an anti-tack agent, an anti-fogging agent, and a coupling finish, as long as they do not essentially impair the advantages of the present invention. These additives may appropriately be selected from conventional additives depending on the purposes, and a suitable amount thereof may be added. There is no special limitation on the method of adding the additives. It may be carried out by melting and kneading, or mixing in the state of a solution.

The double bonds originating from the conjugated diene monomers, which double bonds are left uncyclized and remains as they were, are apt to be oxidized and deteriorate because of their chemical structure. To add an antioxidant to the cyclized conjugated diene polymer having a small degree of decrease in unsaturated bonds is advantageous. There is no further special requirement for the antioxidant, if the antioxidant is commonly used in the fields of adhesives, resin materials, and rubber materials. Examples of the antioxidant are phenol antioxidants and phosphite antioxidants.

The antioxidant may be used singly, or two or more antioxidants may be combined. The amount of the antioxidant should preferably be not more than 500 ppm by mass, more preferably not more than 400 ppm, and particularly preferably not more than 300 ppm. The antioxidant in a too large amount is apt to lower the oxygen absorption. The lower limit of the amount of the antioxidant should preferably be 10 ppm, more preferably 20 ppm. The cyclized conjugated diene polymer without an antioxidant may deteriorate at high temperatures, and the mechanical strength thereof may decrease after the absorption of oxygen gas.

A typical example of the catalyst the function of which is to improve oxygen absorption is a salt of a transition metal. Although the cyclized conjugated diene polymer according to the invention shows sufficient oxygen absorption without a salt of a transition metal, the inclusion of a salt of a transition metal makes the polymer more excellent in the oxygen absorption. However, when a salt of a transition metal is employed in the present invention, care should be taken to ensure that the addition of such a metal component does not adversely affect the transparency and the use of the polymer. Preferable examples of the salt may include cobalt (II) oleate, cobalt (II) naphthenate, cobalt (II) 2-ethylhexanate, cobalt (II) stearate, and cobalt (II) neodecanate. Among them, more preferable are cobalt (II) 2-ethylhexanate, cobalt (II) stearate, and cobalt (II) neodecanate. The amount of the transition metal incorporated into the oxygen-absorbing layer is typically from 10 to 10,000 ppm, preferably from 20 to 5,000 ppm, more preferably from 50 to 5,000 ppm.

The light initiator is a compound that has the function of expediting the beginning of the oxygen absorbing reaction when the cyclized conjugated diene polymer is irradiated with energy rays. For the light initiator may be employed those described in the Japanese translated publication No. 2003-504042. When the light initiator is added to the polymer, the amount thereof is typically from 0.001 to 10% by mass, preferably from 0.01 to 1% by mass, to the total amount of the cyclized conjugated diene polymer.

There is no limitation on the method of forming the oxygen-absorbing layer. Compression molding, injection molding, solvent casting, melt extrusion, and other methods may be employed. Alternatively, the material for the oxygen-absorbing layer may be co-extruded with a resin for the protective resin layer, which will be described hereinafter.

For the oxygen-absorbing layer of the present invention may be used not only two or more cyclized conjugated diene polymers but also the polymer(s) with other resins. For example, a mixture of the cyclized conjugated diene polymer(s) and an acrylic resin, an alicyclic polymer, a chain polyolefin, a polyester, a polyamide, etc. may be used. A laminate formed from the cyclized conjugated diene polymer(s) and those other polymers may also be employed.

The protective resin layer employed in the present invention is a layer mainly to keep the mechanical strength of the laminate for a luminescent element. Because the oxygen-absorbing layer and the gas-barrier layer are normally very thin films, the protective resin layer serves as a support or framework of the laminate for a luminescent element. For this reason, the resin used for the protective layer has to have transparency and mechanical properties required to answer the purposes of the use of the laminate. The resin used for the protective resin layer should preferably have a tensile strength of not less than 400 kg/cm² measured according to JIS K7113. Specific examples include acrylic resin, alicyclic polymer, polyester, polyethylene, polypropylene, polystyrene, polycarbonate, polyvinyl chloride, polyvinyl alcohol, ethylene-vinylalcohol copolymer, polyvinylidene chloride, polyacrylonitrile, and polyamide. From the viewpoints of optical properties, mechanical strength, and heat resistance, polyester, acrylic resin, and alicyclic polymer are preferable, with alicyclic polymer more preferable.

The alicyclic polymer suitably employed in the present invention specifically includes (1) norbornene polymers, (2) polymers of cycloolefins with a single ring, (3) polymers of cyclic conjugated dienes, (4) polymers of vinylalicyclic hydrocarbons, and mixtures thereof. Among them are preferred norbornene polymers and vinyl alicyclic hydrocarbons from the viewpoints of optical properties, heat resistance, and mechanical properties. The employment of an alicyclic polymer with polar groups for the alicyclic polymer makes it possible to improve the affinity with inorganic substances without lowering the light transmittance.

### (1) Norbornene Polymers

The norbornene polymers used in the present invention may include polymers made through a ring opening polymerization of norbornene monomers, copolymers made through a ring opening copolymerization of norbornene monomers and other monomers that are ring-opening copolymerizable with norbornene monomers, the hydrogenated of the polymers and the copolymers, addition polymers of norbornene monomers, and addition copolymers made through a copolymerization of norbornene monomers and other monomers copolymerizable with norbornene monomers. Among them, most preferable are hydrogenated polymers made through a ring opening polymerization of norbornene monomers, and hydrogenated copolymers made through a ring opening copolymerization of norbornene monomers and other monomers that are ring-opening copolymerizable with norbornene monomers, from the viewpoints of optical properties, heat resistance, and mechanical properties. The norbornene monomers include bicyclo[2.2.1]-hept-2-ene, the popular name of which is norbornene, and its derivatives, which mean norbornene compounds with substituents on the rings, tricyclo [4.3.1^{2,5}.0^{1,6}]-dec-3,7-diene, tetracyclo [7.4.1^{10,13}. 0^{1,9}.0^{2,7}]-tridec-2,4,6,11-tetraene, tetracyclo [4.4.1^{2,5}. 1^{7,10}. 0]-dodec-3-ene, and derivatives thereof, which mean those compounds with substituents on their rings. The substituents on the rings may include alkyl groups, alkylene groups, vinyl groups, and alkoxycarbonyl groups. The norbornene monomers may have two or more kinds of these groups. A single kind of the norbornene monomers, or two or more kinds thereof may be used.

The other monomers that are ring-opening copolymerizable with the norbornene monomers may include, for example, cycloolefin monomers with a single ring such as cyclohexene, cycloheptene, and cyclooctene. A single kind of these other monomers, or two or more kinds thereof may be used. When the norbornene monomers and the monomers that are ring-opening copolymerizable with the norbornene monomers are subject to addition copolymerization, the ratio of the total mass of the first units originating from the norbornene monomers to the total mass of the second units originating from the other monomers in the addition copolymer should be decided in the range from 30:70 to 99:1, preferably from 50:50 to 97:3, more preferably from 70:30 to 95:5.

(2) Polymers of Cycloolefins with a Single Ring

Examples of the polymers of cycloolefins with a single ring may include addition polymers of cycloolefin monomers each with a single ring, such as cyclohexene, cycloheptene, and cyclooctene.

### (3) Polymers of Cyclic Conjugated Dienes

The polymers of cyclic conjugated dienes may include polymers made by 1,2-addition polymerization or 1,4-addition polymerization of cyclic conjugated diene monomers such as cyclopentadiene and cyclohexadiene, and the hydrogenated of the polymers.

### (4) Polymers of Vinylalicyclic Hydrocarbons

The polymers of vinylalicyclic hydrocarbons may include, for example, polymers of vinylalicyclic hydrocarbon monomers such as vinylcyclohexene and vinylcyclohexane, and the hydrogenated of the polymers; the hydrogenated compounds obtained by hydrogenating the aromatic ring fragments of polymers of vinylaromatic hydrocarbon monomers such as α-methylstyrene; and the hydrogenated of copolymers of the vinylalicyclic hydrocarbon monomers and the vinylaromatic hydrocarbon monomers, and the hydrogenated of terpolymers of these monomers and other monomers polymerizable with these monomers.

The kinds of the polar groups in the alicyclic polymers with polar groups may include, for example, polar groups with an oxygen atom, a nitrogen atom, a sulfur atom, and a silicon atom, and halogen atoms. From the viewpoints of the dispersibility of inorganic compounds and the compatibility with other resins, groups with an oxygen atom and/or a nitrogen atom are preferable. Examples of the polar group may include the carboxyl group, the carbonyloxycarbonyl group, the epoxy group, the hydroxyl group, the oxy group, the ester group, the silanol group, the silyl group, the amino group, the nitrile group and the sulfone group.

The gas-barrier layer employed in the present invention will be satisfactory if it has commonly known gas-barrier properties. The gas-barrier layer should preferably has an oxygen permeability of not more than 5 mL/m²/day, more preferably not more than 3 mL/m²/day, further more preferably not more than 1 mL/m²/day. The gas-barrier layer with a small value of the oxygen permeability is able to limit the amount of the oxygen gas that permeates through the gas-barrier layer and reaches the oxygen-absorbing layer, so that the oxygen-absorbing layer is able to completely absorb the oxygen gas that has reached the oxygen-absorbing layer through the gas-barrier layer. Thus, the laminate as a whole is able to prevent the permeation of oxygen gas. The gas-barrier layer with this function may be anything with the oxygen permeability within the above-mentioned range. The user can choose a gas-barrier layer serving for the purposes of the use, considering the properties of the material of the layer and the thickness of the layer. The oxygen permeability may be measured with a commercially available measuring device of the oxygen permeation rate, an example of which an OXY-TRAN device made by MOCON, Inc., under an atmosphere the temperature of which is 25° C. and the humidity of which is 75% RH.

The gas-barrier layer may include an inorganic gas-barrier layer and a resin gas-barrier layer.

The inorganic gas-barrier layer generally exhibits very high gas-barrier performance, and even a thin film thereof works very well. The inorganic gas-barrier layer may be an evaporated film made of, for example, an oxide, a nitroxide, a sulfide of a metal such as silicon, magnesium, titanium, aluminum, indium, tin, tungsten, cerium, and zirconium. The gas-barrier layer is often used as the outermost layer of the laminate for a luminescent element, and therefore it sometimes needs a certain hardness so as not to be injured. The inorganic gas-barrier layer is especially appropriate for the use like this.

For the resin gas-barrier layer, films made of polyvinyl alcohol, ethylene-vinyl alcohol copolymer, polyvinylidene chloride, polyacrylonitrile, polyamide 6, polyester, and acrylic resin may preferably be used. Polyvinylidene chloride and polyester, with little water vapor permeability, are especially appropriate materials. From the viewpoints of transparency and hardness, acrylic resin is excellent. When a sheet with a thickness of 1 mm or more is used for the gas-barrier layer, many other resins can serve the purpose. Examples of such resins are polyethylene, polystyrene, polycarbonate, polyvinyl chloride, and alicyclic polymers. In view of their optical properties, mechanical strength, and heat resistance, alicyclic polymers are preferable, with norbornene polymers more preferable. The gas-barrier layer made of a norbornene polymer has high transparency and is capable of doubling as the protective resin layer explained hereinbefore.

A preferable embodiment of the laminate for a luminescent element according to the present invention is a laminate comprising the protective resin layer, the gas-barrier layer, and the oxygen-absorbing layer placed inside those layers, wherein the entire layers outer than the oxygen-absorbing layer have an oxygen permeability of not more than 5 mL/m²/day, preferably not more than 3 mL/m²/day, more preferably not more than 1 mL/m²/day. Furthermore, the oxygen permeability of the combined layers of the protective resin layer and the gas-barrier layer should desirably be smaller than the oxygen absorption rate of the cyclized conjugated diene polymer. When the oxygen permeability of the combined layers is larger than the oxygen absorbing rate of the cyclized conjugated diene polymer, oxygen gas that has permeated through the combined layers and reached the oxygen-absorbing layer may not be sufficiently absorbed, and there is a probability that the oxygen gas may enter the inside of the container. A luminescent element provided with the substrate and the sealing container made of the laminate according to the present invention can emit light from the side of the sealing container, as well as the side of the substrate in the conventional manner. This makes it possible to provide organic EL panels capable of emitting light from both sides, and organic EL panels employing opaque materials for the substrate, yet capable of emitting light from the side of the sealing container, contrary to the conventional manner.

Referring to FIG. 1, we will explain an embodiment of the luminescent element according to the present invention. A luminescent element 13 is composed of a luminescent body 10 comprising an anode 4, a luminescent layer 5, and a cathode 6 layered one by one; a substrate 11 on which the luminescent body 10 is placed; and a sealing container 12 so placed on the substrate 11 that the sealing container covers the luminescent body. To stick the sealing container 12 onto the substrate 11 may normally be used an epoxy adhesive or the like. Especially preferable is an adhesive with small oxygen permeability. A laminate for a luminescent element 14, of which the substrate 11 and the sealing container 12 are made, is composed of a gas-barrier layer 1, a resin protective layer 2, and an oxygen-absorbing layer 3. The laminate 14 is so placed that the oxygen-absorbing layer 3 forms the inside layer of the sealing container 12, or the layer on the side of the luminescent body 10. Also, the part of the substrate 11 that is exposed to the outside air should be so made that the oxygen-absorbing layer 3 does not exist in the part, or the part should be covered with a material such as epoxy resin so as to hardly absorb oxygen gas. It is desirable that the laminate for a luminescent element 14 should be highly transparent and have a light transmittance of 85% or more at wavelengths from 400 nm to 650 nm.

When the laminate for a luminescent element 14 is employed for a luminescent element 13 as shown in FIG. 1, the oxygen-absorbing layer 3 absorbs oxygen gas remaining in the sealing container 12 first, which creates an non-oxygen atmosphere in the sealing container 12. After that, the oxygen absorbing layer 3 absorbs a small amount of oxygen gas permeating into the inside of the sealing container from the outside atmosphere through the gas-barrier layer 1 and the protective resin layer 2, and is capable of keeping the non-oxygen atmosphere in the sealing container 12. Although the side faces of the sealing container are shown as large ones, actual luminescent elements have side faces with areas much smaller than that of the bottom face of the sealing container. Also, because the side faces need not be transparent at all, any materials with small oxygen permeability may be used for them. Needless to say, the side faces of the sealing container 12 may be formed from the same material as the bottom face thereof.

FIG. 2 shows an example of the luminescent element 13 in which the laminate for a luminescent element 14 according to the present invention is used for the sealing container 12 and another material, such as an alicyclic polymer, is employed for the substrate 11. In this example, there is a probability that a small amount of oxygen gas may permeate into the inside of the sealing container through the substrate 11. The employment of a thicker substrate 11, which is able to reduce the amount of oxygen gas permeating through the substrate, will answer the problem and this example can be applied to ordinary luminescent elements without any problems.

### EXAMPLES

The invention will be described more specifically by way of examples. In the followings, “parts” and “%” are based on the mass unless noted otherwise.

Various properties were measured and evaluated in the following ways:

### (1) Degree of Decrease in Unsaturated Bonds in Cyclized Conjugated Diene Polymer

The degree of decrease in unsaturated bonds were obtained through proton magnetic resonance based on the methods taught in documents (a) and (b) below:

(a) M. a. Golub and J. Heller. Can. J. Chem, 41, 937 (1963)
(b) Y. Tanaka and H. Sato, J. Poiym. Sci: Poiy. Chem. Ed., 17, 3027 (1979)

The calculation was done according to following equations. In the equations, “SBT” denotes the area of the entire proton peaks and “SBU” the area of the peaks by the protons directly bonded to the double bonds, in the conjugated diene monomer parts of the conjugated diene polymer. “SAT” denotes the area of the entire proton peaks and “SAU” the area of the peaks by the protons directly bonded to the double bonds, in the conjugated diene monomer parts of the cyclized conjugated diene polymer. Then, “SB”, which denotes the proportion of the area of the peaks by the protons directly bonded to the double bonds to the area of the entire proton peaks before the cyclization, is expressed by: SB=SBU/SBT. On the other hand, “SA”, which denotes the proportion of the area of the peaks by the protons directly bonded to the double bonds to the area of the entire proton peaks after the cyclization, is expressed by: SA=SAU/SAT. Therefore the degree of decrease in unsaturated bonds is expressed by the following equation:

The degree of decrease in unsaturated bonds(%)=100×(SB−SA)/SB

(2) Light Transmittance at Wavelengths Ranging from 400 nm to 650 nm

The light transmittance at wavelengths ranging from 400 nm to 650 nm was measured according to JIS K7361-1. The light transmittance was calculated from the amount of light transmitted by a 40 mm×40 mm square test piece with a turbidimeter, or a Model NDH2000 Hazemeter produced by Nippon Denshoku Industries, Co., Ltd.

### (3) Amount of Absorbed Oxygen Gas

A sample was subjected to compression molding at 100° C. in an atmosphere of nitrogen gas and the obtained mold was stretched to a film of 10 μm in thickness. The film was cut to a 100 mm×100 mm piece, which was used for the measurement of the amount of absorbed oxygen gas. The test piece was placed, together with 200 mL of air, in a 150 mm×220 mm bag that does not allow oxygen gas to permeate and is formed from a three-layered film composed of a polyethylene terephthalate film (PET)/aluminum foil (Al)/a polyethylene film, and the bag was sealed. The sealed bag was allowed to stand at 23° C., and the concentration of the oxygen gas in the bag was measured with an oximeter at intervals of 24 hours. When the concentration of the oxygen gas ceased decreasing, the absorption of oxygen gas was considered to have become saturated. Then, the amount of oxygen gas absorbed by 1 g of the sample was calculated. The oximeter was a Model HS-750 oxygen gas analyzer produced by Neutronics, Inc.

### (4) Oxygen Absorbing Rate

The rate of oxygen absorption was measured with the same method as the amount of absorbed oxygen gas explained in item (3) above. The amount of the absorbed oxygen gas after 24 hours from the beginning of the measurement was regarded as the rate. The temperature at which the measurement was carried out was 23° C.

### (5) Mass Average Molecular Weight

A value reduced from that of standard polystyrene measured by gel permeation chromatography was regarded as the mass average molecular weight.

### (6) Amount of Included Polar Groups

The amount of a polar group included was obtained by measuring the intensity of a characteristic peak by Fourier transform infrared absorption spectroscopy, which was followed by calibration. For example, the intensity of the peak of an acid anhydride group, which is typically observed at 1760 to 1780 cm⁻¹, was measured and the amount of the included acid anhydride groups was obtained by calibration. In the same way, the intensity of the characteristic peak of the carboxyl group, which is observed at 1700 cm⁻¹, was measured, and the amount of included carboxyl groups was calculated by calibration.

### (7) Proportion of Included Styrene Units

The proportion (% by mole) of styrene units included was measured by ¹H-NMR spectroscopy.

### (8) Oxygen Permeability

The oxygen permeability was measured with the oxygen permeation rate measuring device named “OXY-TRAN” made by MOCON, Inc., under an atmosphere the temperature of which is 25° C. and the humidity of which is 75% RH.

### Working Example 1

In a pressure reactor equipped with a stirrer, a thermometer, a reflux condenser, and a nitrogen gas-introducing pipe were placed 300 parts of a 10 mm×10 mm piece of a polyisoprene that included 73% of cis-1,4-bonding units, 22% of trans-1,4-bonding units, and 5% of 3,4-bonding units, and had a mass average molecular weight of 174,000, and 700 parts of toluene. After the atmosphere in the reactor was replaced with nitrogen gas, the mixture in the reactor was heated to 85° C. and the polyisoprene was completely dissolved in toluene by stirring. 2.4 parts of a p-toluenesulfonic acid that had been so prepared by reflux dehydration in toluene that the water content thereof was 150 ppm or less was introduced in the solution, and the cyclization reaction was carried out at 85° C. The reaction was allowed to continue for four hours. Then, the reaction was terminated by the introduction of a 25% aqueous solution of sodium carbonate including 0.83 part of sodium carbonate. The product was washed three times with 300 parts of ion-exchanged water at 85° C., so that the catalyst residue in the system was removed. A solution including a cyclized polymer was obtained. A phenolic antioxidant, the commercial name of which was IRGANOX 1010 produced by Ciba Specialty Chemicals, Inc., in an amount of 20 ppm to the mass of the cyclized polymer was added to the solution. A part of toluene in the solution was distilled away. The remaining was dried in vacuo and toluene was completely removed. This procedure provided cyclized conjugated diene polymer 1. The degree of decrease in unsaturated bonds, the amount of absorbed oxygen gas, the rate of absorbing oxygen gas, and the mass average molecular weight of polymer 1 were measured. The results are shown in Table 1.

A film of 100 mm in width and 100 μm in thickness was prepared by melt extruding cyclized conjugated diene polymer 1. On the other hand, a sheet of 100 mm in width, 500 mm in length and 1 mm in thickness was prepared from a norbornene polymer, the commercial name of which was ZEONOR 1060, produced by ZEON CORPORATION, by extrusion. The sheet was cut into a square piece with each side of 50 mm, and the film of cyclized conjugated diene copolymer 1 was contact bonded onto one face of the piece. A laminate was obtained. A box container with a bottom face and without a top face, or the opposite of the bottom face being open, the dimensions of which were 40 mm in width, 40 mm in length, and 5 mm in height, was prepared from the laminate by press molding so that the film constituted the inner face of the container. A silica film with a thickness of 120 nm was formed on the outer surface of the box container by vapor deposition. The obtained container was regarded as a sealing container made of the laminate for a luminescent element. Because the cyclized conjugated diene polymer absorbs oxygen gas, the operation was carried out in an atmosphere of nitrogen gas when there was a probability that the film of the cyclized conjugated diene polymer contacted air from the outside. This procedure was also employed in the later steps or processes whenever the same situation arose.

The norbornene sheet, prepared above, was cut into another square piece with each side of 50 mm. A silica film of 120 nm in thickness was formed on one face of the piece by vapor deposition. The oxygen permeability of the square piece with the silica film was 0.8 mL/m²/day. The film of the cyclized conjugated diene polymer prepared above was press bonded to the entire face opposite the face with the silica film of the piece. Thus another laminate for a luminescent layer was prepared. The light transmittance of this laminate was measured. The result of the measurement is shown in Table 2. The laminate was used for the substrate of a luminescent element. The substrate was put on the opening of the sealing container in an atmosphere of nitrogen gas, with the face having the silica film thereon being the outside. An epoxy adhesive was applied to the parts where the substrate contacted the upper rim of the sealing container to stick the former to the latter. Thus, the sealing container was completely sealed with the substrate. This completely sealed container was regarded as a luminescent element. A small hole was formed in the container in an atmosphere of nitrogen gas and a sensor for measuring oxygen concentration was inserted into the container through the hole. The inserted sensor refilled and sealed the hole. Then, the measurement with the sensor confirmed that the concentration of oxygen gas in the space within the sealing container sealed by the substrate was zero. This sealed container for a luminescent element, which is sometimes called paraluminescent element, was allowed to stand in the atmosphere. The sealed space was imagined to be the inside of an organic EL element, and the concentration of oxygen gas was measured after one day, 10 days, and 100 days from the beginning of the experiment. The results are shown in Table 2.

### Working Example 2

Cyclized conjugated diene polymer 2 was prepared. The steps of the preparation were the same as those in Working Example 1, except that the amount of p-toluenesulfonic acid was changed to 2.25 parts and the amount of sodium carbonate added after the cyclization reaction was changed to 0.78 part. A box container and a laminate for a luminescent element were made in the same way as in Working Example 1, except that cyclized conjugated diene polymer 2 was used in place of cyclized conjugated diene polymer 1. The properties of the obtained were evaluated with the same methods as in Working Example 1. The results are shown in Tables 1 and 2.

### Working Example 3

Cyclized conjugated diene polymer 3 was prepared. The steps of the preparation were the same as those in Working Example 1, except that the polyisoprene was changed to a high cis-polyisoprene that included 99% or more of the cis-1,4-bonding units and had a mass average molecular weight of 302,000, the amount of p-toluenesulfonic acid was changed to 2.16 parts, and the amount of sodium carbonate added after the cyclization reaction was changed to 0.75 part. A box container and a laminate for a luminescent element were made in the same way as in Working Example 1, except that cyclized conjugated diene polymer 3 was used in place of cyclized conjugated diene polymer 1. The properties of the obtained were evaluated with the same methods as in Working Example 1. The results are shown in Tables 1 and 2.

### Working Example 4

Cyclized conjugated diene polymer 4 was prepared. The steps of the preparation were the same as those in Working Example 1, except that the polyisoprene was changed to a polyisoprene that included 68% of the cis-1,4-bonding units, 25% of the trans-1,4-bonding units, and 7% of the 3,4-bonding units, and had a mass average molecular weight of 141,000, the amount of p-toluene sulfonic acid was changed to 2.69 parts, and the amount of sodium carbonate added after the cyclization reaction was changed to 1.03 parts. A box container and a laminate for a luminescent element were made in the same way as in Working Example 1, except that cyclized conjugated diene polymer 4 was used in place of cyclized conjugated diene polymer 1. The properties of the obtained were evaluated with the same methods as in Working Example 1. The results are shown in Tables 1 and 2.

### Working Example 5

2.5 parts of maleic anhydride was added to the solution including cyclized conjugated diene polymer 1, obtained in Working Example 1, and the mixture was subjected to an addition reaction at 160° for four hours. A part of toluene in the product solution was distilled away. A phenolic antioxidant, the commercial name of which was IRGANOX 1010 produced by Ciba Specialty Chemicals, Inc., in an amount of 300 ppm to cyclized conjugated diene polymer 1 was added to the product solution. The product solution with the phenolic antioxidant was dried in vacuo, and the remaining toluene and unreacted maleic anhydride were completely removed. This procedure provided a modified cyclized conjugated diene polymer, which will be named cyclized conjugated diene polymer 5. A box container and a laminate for a luminescent element were made in the same way as in Working Example 1, except that cyclized conjugated diene polymer 5 was used in place of cyclized conjugated diene polymer 1. The properties of the obtained were evaluated with the same methods as in Working Example 1. The results are shown in Tables 1 and 2. The result of the measurement of the amount of polar groups included in cyclized conjugated diene polymer 5 is also shown in Table 1.

### Working Example 6

Another modified cyclized conjugated diene polymer, which will be called cyclized conjugated diene polymer 6, was prepared. The steps of the preparation were the same as those in Working Example 5, except that the amount of p-toluenesulfonic acid was changed to 2.25 parts and the amount of sodium carbonate added after the cyclization reaction was changed to 0.78 part. A box container and a laminate for a luminescent element were made in the same way as in Working Example 1, except that cyclized conjugated diene polymer 6 was used in place of cyclized conjugated diene polymer 1. The properties of the obtained were evaluated with the same methods as in Working Example 5. The results are shown in Tables 1 and 2. The result of the measurement of the amount of polar groups included in cyclized conjugated diene polymer 6 is also shown in Table 1.

### Working Example 7

Still another modified cyclized conjugated diene polymer, which will be called cyclized conjugated diene polymer 7, was prepared. The steps of the preparation were the same as those in Working Example 5, except that the polyisoprene was changed to a high cis-polyisoprene that included 99% or more of the cis-1,4-bonding units and had a mass average molecular weight of 302,000, the amount of p-toluenesulfonic acid was changed to 2.16 parts, and the amount of sodium carbonate added after the cyclization reaction was changed to 0.75 part. A box container and a laminate for a luminescent element were made in the same way as in Working Example 1, except that cyclized conjugated diene polymer 7 was used in place of cyclized conjugated diene polymer 1. The properties of the obtained were evaluated with the same methods as in Working Example 5. The results are shown in Tables 1 and 2. The result of the measurement of the amount of polar groups included in cyclized conjugated diene polymer 7 is also shown in Table 1.

### Working Example 8

Further another modified cyclized conjugated diene polymer, which will be called cyclized conjugated diene polymer 8, was prepared. The steps of the preparation were the same as those in Working Example 5, except that the polyisoprene was changed to a polyisoprene that included 68% of the cis-1,4-bonding units, 25% of the trans-1,4-bonding units, and 7% of the 3,4-bonding units, and had a mass average molecular weight of 141,000, the amount of p-toluenesulfonic acid was changed to 2.69 parts, and the amount of sodium carbonate added after the cyclization reaction was changed to 1.03 parts. A box container and a laminate for a luminescent element were made in the same way as in Working Example 1, except that cyclized conjugated diene polymer 8 was used in place of cyclized conjugated diene polymer 1. The properties of the obtained were evaluated with the same methods as in Working Example 5. The results are shown in Tables 1 and 2. The result of the measurement of the amount of polar groups included in cyclized conjugated diene polymer 8 is also shown in Table 1.

### Working Example 9

In an autoclave equipped with a stirrer were placed 8000 parts of cyclohexane, 320 parts of styrene, and 19.9 millimoles of n-butylithium as a 1.56-mol/liter hexane solution. The temperature inside the autoclave was raised to 60° C. and a polymerization reaction was carried out for 30 minutes at the temperature. The conversion of styrene in the polymerization was almost 100%. A part of the polymer solution, which will be called the first polymer solution, was taken and the mass average molecular weight of the polystyrene was measured. It was 14,800. Then, 1840 parts of isoprene was gradually and continuously added to the first polymer solution over 60 minutes, while the temperature inside the autoclave was being so controlled that it did not exceed 75° C. After the completion of the addition, the mixture of the first polymer solution and isoprene was allowed to further react for one hour at 70° C. At this point of time, the degree of polymerization conversion was almost 100%. The polymerization reaction was terminated by adding 0.362 part of a 1% aqueous solution of a sodium salt of β-naphthalenesulfonic acid-formalin-condensate to the reacted mixture, which will be called the second polymer solution. Block copolymer a with a diblock structure composed of the polystyrene blocks and the polyisoprene blocks was obtained. A part of block copolymer a was taken and the mass average molecular weight was measured. It was 178,000.

Then, 18.4 parts of xylenesulfonic acid was added to the second polymer solution, and the mixture of the second polymer solution and xylenesulfonic acid was subjected to a cyclization reaction at 80° C. for four hours. The cyclization reaction was terminated by adding a 25% aqueous solution of sodium carbonate including 6.2 parts of sodium carbonate. The reaction product was stirred at 80° C. for thirty minutes. The obtained polymer product solution was filtered by using a glass filter with a pore size of 1 μm. This filtration removed cyclization catalyst residue, and a solution including block copolymer A was obtained. A phenolic antioxidant, the commercial name of which was IRGANOX 1010 produced by Ciba Specialty Chemicals, Inc., in an amount of 0.062 part to 1000 parts of the polymer product solution was added to the solution. The solvent was distilled away at 120° C. under stirring. When the solids concentration reached 85% by mass, the temperature was raised to 160° C. and the remaining solvent was completely removed. This procedure provided cyclized conjugated diene polymer 9, which is a block copolymer. A box container and a laminate for a luminescent element were made in the same way as in Working Example 1, except that cyclized conjugated diene polymer 9 was used in place of cyclized conjugated diene polymer 1. The properties of the obtained were evaluated with the same methods as in Working Example 1. The results are shown in Tables 1 and 2. The result of the measurement of the styrene-unit content of cyclized conjugated diene polymer 9 is also shown in Table 1.

### Working Example 10

1000 parts of the polymer product solution including cyclized conjugated diene polymer 9 was stirred at 120° C., and the solvent was distilled away until the solids concentration reached 80% by mass. To this concentrate was added 4.41 parts of maleic anhydride, and the mixture was subjected to an addition reaction at 160° C. for one hour. Then, unreacted maleic anhydride and the solvent were removed. After 0.062 part of a phenolic antioxidant, the commercial name of which was IRGANOX 1010 produced by Ciba Specialty Chemicals, Inc., was added to the obtained, the mixture of the obtained and the antioxidant was transferred to a container coated with polyethylene tetrafluoride. The mixture was dried under reduced pressure at 75° C., and a modified cyclized conjugated diene polymer with maleic anhydride added, which will be called cyclized conjugated diene polymer 10, was obtained. A box container and a laminate for a luminescent element were made in the same way as in Working Example 1, except that cyclized conjugated diene polymer 10 was used in place of cyclized conjugated diene polymer 1. The properties of the obtained were evaluated with the same methods as in Working Example 1. The results are shown in Tables 1 and 2. The results of the measurements of the styrene-unit content and the amount of polar groups of cyclized conjugated diene polymer 10 are also shown in Table 1. The cyclized conjugated diene polymers obtained both in Working Examples 9 and 10 did not essentially include gel that is not dissolved in toluene.

### Working Example 11

Cyclized conjugated diene polymer 11 was prepared. The steps of the preparation were the same as those in Working Example 1, except that in place of the polyisoprene a polyisoprene that included 73% of the cis-1,4-bonding units, 22% of the trans-1,4-bonding units, and 5% of the 3,4-bonding units, and had a mass average molecular weight of 154,000 was used, the reaction temperature was 80° C., the amount of the catalyst was 2.19 parts, and the reaction time was four hours. A box container and a laminate for a luminescent element were made in the same way as in Working Example 1, except that cyclized conjugated diene polymer 11 was used in place of cyclized conjugated diene polymer 1. The properties of the obtained were evaluated with the same methods as in Working Example 1. The results are shown in Tables 1 and 2.

### Comparative Example 1

A polyisoprene that included 73% of the cis-1,4-bonding units, 22% of the trans-1,4-bonding units, and 5% of the 3,4-bonding units, and had a mass average molecular weight of 174,000 was subjected to compression molding at 100° C., so that a polyisoprene film with a thickness of 120 μm. This polyisoprene film was cut into a 100 mm×100 mm piece, thus a test piece was prepared. A box container and a laminate for a luminescent element were made in the same way as in Working Example 1, except that this test piece was used in place of cyclized conjugated diene polymer 1. The properties of the obtained were evaluated with the same methods as in Working Example 1. The results are shown in Tables 1 and 2. The cyclization reaction was not carried out in this comparative example, and the degree of decrease in unsaturated bonds was 0%.

### Comparative Example 2

A 20% toluene solution of β-pinene polymer, or a YS resin PXN-1150N produced by YASUHARA CHEMICAL Co., Ltd., was prepared, and the solution was subjected to precipitation purification. A β-pinene polymer with the antioxidant removed was obtained. A test piece was prepared and the evaluation of the test piece was carried out with the same methods as in Comparative Example 1, except that the β-pinene polymer with the antioxidant removed was used in place of the polyisoprene. The results are shown in Tables 1 and 2. This comparative example is an example in which a polymer other than cyclized conjugated diene polymers was used.

### Comparative Example 3

An ethylene-cyclopentene copolymer that had 15.5% by mole of the cyclopentene units and a mass average molecular weight of 83,500 was prepared based on Example 16 of Patent Document 3. A 30% toluene solution of the ethylene-cyclopentene copolymer was prepared. The solution was applied to a polyethylene terephthalate film with a thickness of 50 μm, and the solution on the film was dried. A laminate film including an ethylene-cyclopentene copolymer film with a thickness of 120 μm was obtained. The copolymer film was peeled off from the polyethylene terephthalate film, and the copolymer film was cut into a 100 mm×100 mm piece. Thus a test piece was prepared. The evaluation of the test piece was carried out with the same method as in Comparative Example 1, except that the obtained test piece was used in place of the polyisoprene. The results are shown in Tables 1 and 2. This comparative example is another example in which a polymer other than cyclized conjugated diene polymers was used.

### Comparative Example 4

1000 parts of the polymer product solution, the solids concentration of which was 20.9%, including block copolymer a, obtained in Working Example 9, was stirred at 120° C., and the solvent was distilled away until the solids concentration reached 80% by mass. To this concentrate was added 4.41 parts of maleic anhydride, and the mixture was subjected to an addition reaction at 160° C. for one hour. Then, unreacted maleic anhydride and the solvent were removed at 160° C. After 0.062 part of a phenolic antioxidant, the commercial name of which was IRGANOX 1010 produced by Ciba Specialty Chemicals, Inc., was added to the obtained, the mixture of the obtained and the antioxidant was subjected to flow casting on a container coated with polyethylene tetrafluoride. The mixture was dried under reduced pressure at 75° C., and a modified cyclized conjugated diene polymer with maleic anhydride added was obtained. A box container and a laminate for a luminescent element were made in the same way as in Working Example 1, except that the modified cyclized conjugated diene polymer was used in place of cyclized conjugated diene polymer 1. The properties of the obtained were evaluated with the same methods as in Working Example 10. The results are shown in Tables 1 and 2. The results of the measurements of the styrene-unit content and the amount of polar groups of the modified cyclized conjugated diene polymer are also shown in Table 1. The cyclization reaction was not carried out in this comparative example, and the degree of decrease in unsaturated bonds was 0%.

TABLE 1

| | Mass | Degree of | | Oxygen | | Styrene- |
|---|---|---|---|---|---|---|
| | average | decrease in | Oxygen | absorption | Amount of | unit |
| | molecular | unsaturated | absorption | rate | polar groups | content |
| | weight | bonds (%) | (mL/g) | (mL/m²/day) | (mmol/100 g) | (%) |
| W. Ex. 1 | 130,500 | 64 | 80 | 79 | — | — |
| W. Ex. 2 | 139,800 | 54 | 68 | 68 | — | — |
| W. Ex. 3 | 226,500 | 61 | 68 | 70 | — | — |
| W. Ex. 4 | 98,700 | 66 | 126 | 95 | — | — |
| W. Ex. 5 | 131,300 | 65 | 79 | 79 | 18 | — |
| W. Ex. 6 | 140,600 | 56 | 70 | 61 | 21 | — |
| W. Ex. 7 | 227,800 | 62 | 72 | 68 | 11 | — |
| W. Ex. 8 | 98,900 | 67 | 120 | 88 | 17 | — |
| W. Ex. 9 | 132,800 | 57 | 50 | 54 | — | 15 |
| W. Ex. 10 | 137,400 | 57 | 60 | 61 | 21 | 15 |
| W. Ex. 11 | 141,000 | 48 | 50 | 58 | — | — |
| Co. Ex. 1 | 174,000 | — | 4 | 5 | — | — |
| Co. Ex. 2 | — | — | 4 | 9 | — | — |
| Co. Ex. 3 | 83,500 | — | 0.8 | 2 | — | — |
| Co. Ex. 4 | 178,000 | — | 4 | 5 | 22 | 15 |

Notes:
“W. Ex.” denotes “Working Example”, and
“Co. Ex.” “Comparative Example”.

TABLE 2

| | Light | | | |
|---|---|---|---|---|
| | transmittance | Oxygen concentration (%) | | |
| | (%) | After 1 day | After 10 days | After 100 days |
| W. Ex. 1 | 92 | 0.001> | 0.001> | 0.001> |
| W. Ex. 2 | 91 | 0.001> | 0.001> | 0.001> |
| W. Ex. 3 | 91 | 0.001> | 0.001> | 0.001> |
| W. Ex. 4 | 91 | 0.001> | 0.001> | 0.001> |
| W. Ex. 5 | 91 | 0.001> | 0.001> | 0.001> |
| W. Ex. 6 | 90 | 0.001> | 0.001> | 0.001> |
| W. Ex. 7 | 90 | 0.001> | 0.001> | 0.001> |
| W. Ex. 8 | 89 | 0.001> | 0.001> | 0.001> |
| W. Ex. 9 | 91 | 0.001> | 0.001> | 0.001> |
| W. Ex. 10 | 91 | 0.001> | 0.001> | 0.001> |
| W. Ex. 11 | 91 | 0.001> | 0.001> | 0.001> |
| Co. Ex. 1 | 78 | 0.001> | 0.003 | 0.036 |
| Co. Ex. 2 | 82 | 0.001> | 0.068 | 0.72 |
| Co. Ex. 3 | 70 | 0.001> | 0.003 | 0.16 |
| Co. Ex. 4 | 72 | 0.001> | 0.002 | 0.16 |

Notes:
“W. Ex.” denotes “Working Example”, and
“Co. Ex.” “Comparative Example”.

As understood from the results of the working examples, the paraluminescent elements according to the present invention were able to keep the oxygen concentration within the space inside the sealing container at less than 0.001%, which was a measurable limit. In other words, the paraluminescent elements were able to maintain a non-oxygen state within the sealed space almost completely. On the other hand, as understood from the results of the comparative examples, when the laminate according to the present invention was not employed, the oxygen concentration within the sealed container increased as time passed, and the space inside the container could not completely be kept in a non-oxygen state.

### INDUSTRIAL APPLICABILITY

The laminate for a luminescent element according to the present invention is capable of providing substrates and/or sealed containers for luminescent elements, which is transparent, made of the resin, and capable of doubling as oxygen absorbing members. The present invention makes it possible to provide novel flexible organic EL elements whose both sides have light transmittance.

1. A laminate for a luminescent element which comprises:
an oxygen-absorbing layer including a cyclized conjugated diene polymer obtained by subjecting a conjugated diene polymer to a cyclizing reaction, said cyclized conjugated diene polymer having a degree of decrease in unsaturated bonds, which is a ratio of the difference between the number of the unsaturated bonds in the conjugated diene polymer and the number of the unsaturated bonds in the cyclized conjugated diene polymer to that of the unsaturated bonds in the conjugated diene polymer, of not less than 10%, and a gas-barrier layer.

2. The laminate according to claim 1, wherein the cyclized conjugated diene polymer has an oxygen absorption of not less than 5 mL/g.

3. The laminate according to claim 1, wherein the oxygen-absorbing layer absorbs oxygen from its surface at a rate of not less than 1 mL/m²/day.

4. The laminate according to claim 1, wherein the cyclized conjugated diene polymer is a modified cyclized conjugated diene polymer.

5. The laminate according to claim 1, wherein the gas-barrier layer has an oxygen permeability of not more than 5 mL/m²/day.

6. The laminate according to claim 1, wherein the laminate has a light transmitted of not less than 85% at a wavelength ranging between 400 nm and 650 nm.

7. The laminate according to claim 1, wherein the conjugated diene polymer is a copolymer of a conjugated diene monomer and at least one other monomer.

8. The laminate according to claim 1, wherein said other monomer is styrene.

9. A luminescent element comprising a substrate, an luminescent body of the luminescent element placed on the substrate, and a sealing container so placed that the sealing container covers the entire luminescent body, wherein the substrate and/or the sealing container is formed from the laminate according to claim 1.
